(19) United States
(12) Patent Application Publication
(10) Pub. No.: US 2025/0351377 A1
(43) Pub. Date: Nov. 13, 2025

(54) VARIABLE RESISTANCE MEMORY DEVICE AND METHOD OF FABRICATING THE SAME

(71) Applicant: SAMSUNG ELECTRONICS CO., LTD., SUWON-SI (KR)

(72) Inventors: Hyungjong Jeong, Suwon-si (KR); Youngkeol Kim, Suwon-si (KR); Junho Park, Suwon-si (KR); Byoungjae Bae, Suwon-si (KR); Kyungchul Lee, Suwon-si (KR)

(21) Appl. No.: 19/202,245

(22) Filed: May 8, 2025

(30) Foreign Application Priority Data
May 13, 2024 (KR) 10-2024-0062748

(51) Int. Cl. H10B 61/00

(52) U.S. Cl. CPC H10B 61/10

(57) ABSTRACT

A method of fabricating a variable resistance memory device includes preparing a substrate having a cell area and a peripheral area, forming magnetic tunnel junction structures in the cell area, forming an interlayer insulating layer covering the cell area and the peripheral area, forming a hard mask conformally covering the interlayer insulating layer, etching a portion of the hard mask to form first recesses in the cell area and a second recess in the peripheral area, forming a plurality of first openings in the interlayer insulating layer by using the first recesses of the hard mask in the cell area in a selective etch process and forming a second opening in the interlayer insulating layer by using the second recess of the hard mask in the peripheral area in the selective etch process, and completely removing the hard mask in the cell area and the peripheral area.

### CROSS-REFERENCE TO RELATED APPLICATION

This application is based on and claims priority under 35 U.S.C. § 119 to Korean Patent Application No. 10-2024-0062748, filed on May 13, 2024 in the Korean Intellectual Property Office, the disclosure of which is incorporated by reference in its entirety herein.

### 1. TECHNICAL FIELD

Embodiments of the present inventive concept relate to a variable resistance memory device and a method of fabricating the same, and more particularly, to a variable resistance memory device including a magnetic tunnel junction (MTJ) structure and a method of fabricating the variable resistance memory device.

### 2. DISCUSSION OF RELATED ART

There has been an increasing consumer demand for electronic products with higher speed and lower power consumption along with the advancement of the information society. Semiconductor devices embedded in the electronic products have required faster read/write operations and lower operating voltages to meet this demand. Research is being conducted concerning highly integrated variable resistance memory devices to provide high-speed read and write operations which are non-volatile. In particular, significant research has been conducted concerning variable resistance memory devices that utilize the magnetoresistance characteristics of an MTJ.

### SUMMARY

Embodiments of the present inventive concept provide a highly reliable variable resistance memory device and a method of fabricating the same by completely removing a hard mask including a conductive material prior to a subsequent polishing process.

The objects to be achieved by embodiments of the present inventive concept are not limited to the technical objects described above and other objects that are not stated herein will be clearly understood by those skilled in the art from the following specifications.

According to an embodiment of the present inventive concept, a method of fabricating a variable resistance memory device includes preparing a substrate having a cell area and a peripheral area surrounding the cell area. A plurality of magnetic tunnel junction (MTJ) structures is formed in the cell area. An interlayer insulating layer is formed covering the cell area and the peripheral area. The interlayer insulating layer having a step difference between the cell area and the peripheral area. A hard mask is formed that conformally covers the interlayer insulating layer in the cell area and the peripheral area. A portion of the hard mask is etched to form a plurality of first recesses in the cell area and a second recess in the peripheral area. A plurality of first openings is formed in the interlayer insulating layer by using the plurality of first recesses of the hard mask in the cell area in a selective etch process and a second opening is formed in the interlayer insulating layer by using the second recess of the hard mask in the peripheral area in the selective etch process. The hard mask is completely removed in the cell area and the peripheral area. A contact forming layer is formed that fills the plurality of first openings of the interlayer insulating layer in the cell area and the second opening of the interlayer insulating layer in the peripheral area.

According to an embodiment of the present inventive concept, a method of fabricating a variable resistance memory device includes preparing a substrate having a cell area and a peripheral area surrounding the cell area. A plurality of magnetic tunnel junction (MTJ) structures is formed in the cell area. A capping layer covering the plurality of MTJ structures is formed in the cell area. A first insulating stopper layer is formed on the capping layer in the cell area. An interlayer insulating layer is formed covering the cell area and the peripheral area. The interlayer insulating layer has a step difference between the cell area and the peripheral area. A second insulating stopper layer that conformally covers the interlayer insulating layer is formed in the cell area and the peripheral area. A hard mask that conformally covers the second insulating stopper layer is formed in the cell area and the peripheral area. A portion of the hard mask is etched to form a plurality of first recesses in the cell area and a second recess in the peripheral area. A plurality of first openings is formed that pass through the second insulating stopper layer and the interlayer insulating layer by using the plurality of first recesses of the hard mask in the cell area in a selective etch process and a second opening is formed passing through the second insulating stopper layer and the interlayer insulating layer by using the second recess of the hard mask in the peripheral area in the selective etch process. The hard mask is completely removed in the cell area and the peripheral area. A contact forming layer is formed that fills the plurality of first openings of the interlayer insulating layer in the cell area and the second opening of the interlayer insulating layer in the peripheral area. A first polishing of the contact forming layer is performed to expose the interlayer insulating layer in the cell area and the second insulating stopper layer in the peripheral area. A second polishing of the contact forming layer is performed to expose the first insulating stopper layer in the cell area and the interlayer insulating layer in the peripheral area.

According to an embodiment of the present inventive concept, a variable resistance memory device includes a substrate having a cell area and a peripheral area surrounding the cell area. A plurality of magnetic tunnel junction (MTJ) structures is disposed in the cell area. The plurality of MTJ structures constitutes a plurality of memory cells. A capping layer covers the plurality of MTJ structures in the cell area. A cell insulating stopper layer is disposed on the capping layer. The cell insulating stopper layer has a multi-layer structure in the cell area. An interlayer insulating layer has at least a portion disposed at a same vertical level as some layers of the multi-layer structure of the cell insulating stopper layer. The interlayer insulating layer has a step difference in the peripheral area. A peripheral insulating stopper layer is disposed on the interlayer insulating layer and has a single-layer structure in the peripheral area. A plurality of first contact structures passes through the cell insulating stopper layer and the capping layer and is connected to the plurality of MTJ structures in the cell area. A second contact structure passes through the peripheral insulating stopper layer and the interlayer insulating layer and is connected to the substrate in the peripheral area. An uppermost layer of the multi-layer structure of the cell insulating stopper layer is connected to the peripheral insulating stopper layer.

### BRIEF DESCRIPTION OF THE DRAWINGS

Embodiments of the present inventive concept will be more clearly understood from the following detailed description taken in conjunction with the accompanying drawings in which:

FIG. 1 is a circuit diagram showing a cell array of a variable resistance memory device according to an embodiment of the present inventive concept;

FIG. 2 is a circuit diagram showing a magnetoresistive memory cell shown in FIG. 1 according to an embodiment of the present inventive concept;

FIG. 3 is a perspective view showing the magnetoresistive memory cell shown in FIG. 2 according to an embodiment of the present inventive concept;

FIG. 4 is a plan view illustrating a variable resistance memory device according to an embodiment of the present inventive concept;

FIG. 5 is a flowchart showing a method of fabricating a variable resistance memory device, according to an embodiment of the present inventive concept;

FIGS. 6 to 23 are cross-sectional views showing a method of fabricating a variable resistance memory device in process order, according to embodiments of the present inventive concept;

FIG. 24 is a configuration diagram of a data processing system including a variable resistance memory device according to an embodiment of the present inventive concept; and

FIG. 25 is a configuration diagram of a data processing system including a variable resistance memory device according to an embodiment of the present inventive concept.

### DETAILED DESCRIPTION OF EMBODIMENTS

Hereinafter, embodiments will be described in detail with reference to the attached drawings.

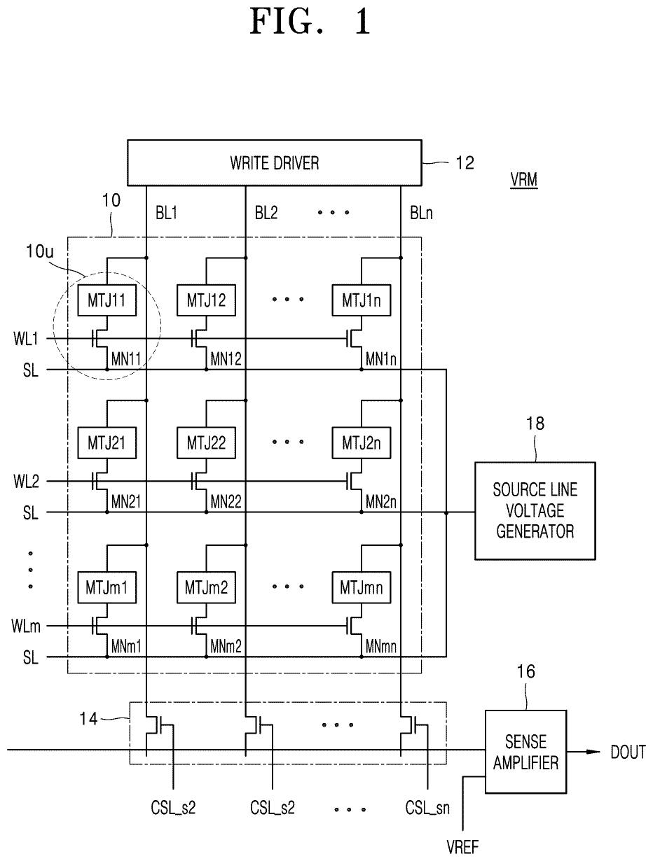

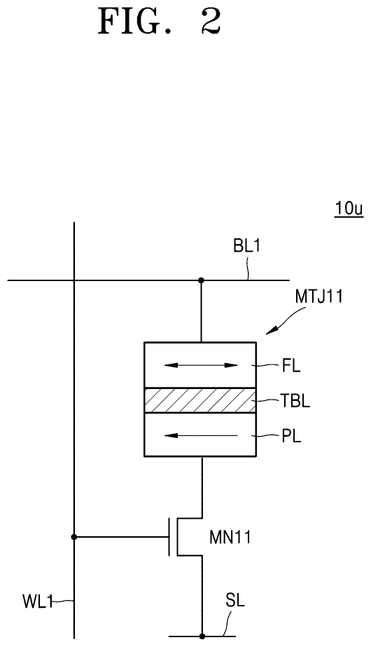

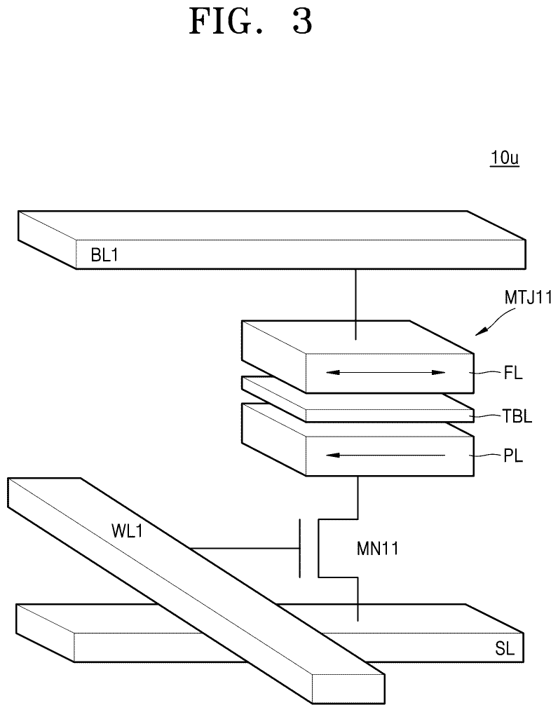

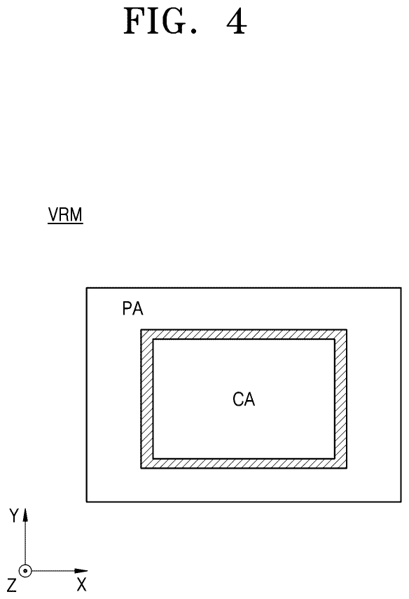

FIG. 1 is a circuit diagram showing a cell array of a variable resistance memory device according to an embodiment. FIG. 2 is a circuit diagram showing a magnetoresistive memory cell shown in FIG. 1. FIG. 3 is a perspective view showing the magnetoresistive memory cell shown in FIG. 2. FIG. 4 is a plan view to explain a variable resistance memory device according to an embodiment.

Referring to FIGS. 1 to 4 together, a variable resistance memory device VRM may include a magnetoresistive memory device according to an embodiment.

As shown in FIG. 1, the magnetoresistive memory device may include magnetoresistive RAM (MRAM). In an embodiment, the variable resistance memory device VRM may include a magnetic tunnel junction (MTJ), which is a variable resistance layer.

The variable resistance memory device VRM may include a magnetoresistive memory cell array 10. The magnetoresistive memory cell array 10 may also be referred to as a cell array. In an embodiment, the magnetoresistive memory cell array 10 may be connected to a write driver 12, a selection circuit 14, a source line voltage generator 18, and a sense amplifier 16.

The magnetoresistive memory cell array 10 may include a plurality of magnetoresistive memory cells 10u. In this specification, a magnetoresistive memory cell 10u may be simply referred to as a memory cell. The magnetoresistive memory cell array 10 may include a plurality of word lines WL1 to WLm and a plurality of bit lines BL1 to BLn in which m and n are each independently an integer greater than or equal to 2. The magnetoresistive memory cell array 10 may have the magnetoresistive memory cell 10u between each of the plurality of word lines WL1 to WLm and each of the plurality of bit lines BL1 to BLn.

In an embodiment, the magnetoresistive memory cell array 10 may include a plurality of cell transistors MN11 to M Nmn having gates connected to the plurality of word lines WL1 to WLm, and a plurality of MTJs MTJ11 to MTJmn that are connected respectively between the plurality of cell transistors MN11 to M Nmn and the plurality of bit lines BL1 to BLn and constitute a variable resistance layer.

The write driver 12 is connected to (e.g., electrically connected thereto) the plurality of bit lines BL1 to BLn, generates a program current based on write data, and provides the program current to the plurality of bit lines BL1 to BLn.

The selection circuit 14 may selectively connect the plurality of bit lines BL1 to BLn to the sense amplifier 16 in response to a plurality of column selection signals CSL_s1 to CSL_sn. The sense amplifier 16 may generate output data DOUT by amplifying a difference between an output voltage signal of the selection circuit 14 and a reference voltage VREF.

In an embodiment, respective sources of the plurality of cell transistors MN11 to M Nmn may be connected to (e.g., electrically connected thereto) a source line SL. To magnetize the plurality of MTJs MTJ11 to MTJmn in the magnetoresistive memory cell array 10, a voltage higher than a voltage applied to the plurality of bit lines BL1 to BLn may be applied to the source line SL. The source line voltage generator 18 may generate a source line driving voltage VSL and provide the source line driving voltage VSL to the source line SL of the magnetoresistive memory cell array 10.

As shown in FIG. 2, in an embodiment the magnetoresistive memory cell 10u may include, for example, a cell transistor MN11 including an NM OS transistor and an MTJ MTJ11. The cell transistor MN11 has a gate connected to the word line WL1 and a source connected to the source line SL. The MTJ MTJ11 is connected (e.g., electrically connected) between a drain of the cell transistor MN11 and the bit line BL1.

As shown in FIG. 3, in an embodiment the MTJ MTJ11 may include a pinned layer PL having a pinned and constant magnetization direction, a free layer FL magnetized in a direction of a magnetic field applied from the outside (e.g., the external environment), and a tunnel barrier layer TBL formed as an insulating layer between the pinned layer PL and the free layer FL.

In some embodiments, the pinned layer PL may include at least one of iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), iron (Fe), nickel (Ni), cobalt (Co), ruthenium (Ru), iridium (Ir), and rhodium (Rh).

In some embodiments, the free layer FL may include a ferromagnetic material containing at least one of iron (Fe), nickel (Ni), or cobalt (Co).

In some embodiments, the tunnel barrier layer TBL may include aluminum oxide (AIO) or magnesium oxide (MgO).

In an embodiment, the MTJ MTJ11 may be provided in a memory cell that constitutes a spin transfer torque (STT)-MRAM.

In an embodiment, for a write operation of the STT-MRAM, a logic high voltage may be applied to the word line WL1 to turn on the cell transistor MN11, and a write current may be applied between the bit line BL1 and the source line SL.

In an embodiment, for the read operation of the STT-MRAM, a logic high voltage may be applied to the word line WL1 to turn on the cell transistor MN11, and a read current may be applied from the bit line BL1 toward the source line SL to determine data stored in the magnetoresistive memory cell 10u according to a resistance value of the MTJ MTJ11 with respect to the read current.

A resistance value of the MTJ MTJ11 varies depending on a magnetization direction of the free layer FL. For example, in an embodiment in the MTJ MTJ11, a magnetization direction of the free layer FL and a magnetization direction of the pinned layer PL may be arranged in parallel to each other. In this embodiment, the MTJ MTJ11 may have a low resistance value and read data (e.g., 0). In an embodiment, in the MTJ MTJ11, the magnetization direction of the free layer FL and the magnetization direction of the pinned layer PL may be antiparallel (e.g., non-parallel) to each other. In this embodiment, the MTJ MTJ11 may have a high resistance value and read data (e.g., 1).

In an embodiment shown in FIG. 3, a horizontal magnetic device in which the magnetization direction of the free layer FL and the magnetization direction of the pinned layer PL are horizontal is shown. However, embodiments of the present inventive concept are not necessarily limited thereto. For example, in some embodiments, a vertical magnetic device in which the magnetization directions of the free layer FL and the pinned layer PL are vertical may also be used.

As shown in FIG. 4, the variable resistance memory device VRM may include a cell area CA and a peripheral area PA surrounding the cell area CA (e.g., in a plan view). In some embodiments, the variable resistance memory device VRM may include a boundary area between the cell area CA and the peripheral area PA.

The cell area CA may include an area in which the magnetoresistive memory cell array 10 of FIG. 1 is disposed. The cell area CA may be an area in which the magnetoresistive memory cell 10u described with reference to FIGS. 1 and 2 is disposed.

In the peripheral area PA, a peripheral circuit and a peripheral transistor that control the magnetoresistive memory cell array 10 in the cell area CA may be disposed. For example, the peripheral area PA may be an area in which a core/ferry circuit is disposed.

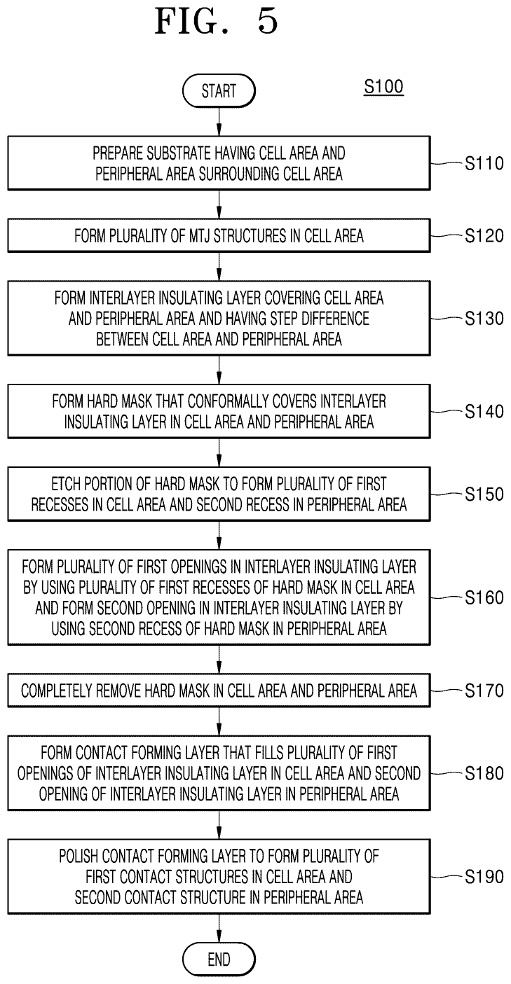

FIG. 5 is a flowchart showing a method of fabricating a variable resistance memory device, according to an embodiment.

Referring to FIG. 5, a method of fabricating a variable resistance memory device S100 may include process sequences of first to ninth operations in blocks S110 to S190.

When an embodiment is implemented differently, a certain process sequence may be performed differently from the described sequence. For example, two processes described sequentially may be performed substantially at the same time, or may be performed in an order opposite to the described order.

The method of fabricating a variable resistance memory device S100 according to an embodiment of the present inventive concept may include a first operation S110 of preparing a substrate having a cell area and a peripheral area surrounding the cell area (e.g., in a plan view), a second operation S120 of forming a plurality of MTJ structures in the cell area, a third operation S130 of forming an interlayer insulating layer covering the cell area and the peripheral area and having a step difference between the cell area and the peripheral area, a fourth operation S140 of forming a hard mask that conformally covers the interlayer insulating layer in the cell area and the peripheral area, a fifth operation S150 of etching a portion of the hard mask to form a plurality of first recesses in the cell area and a second recess in the peripheral area, a sixth operation S160 of forming a plurality of first openings in the interlayer insulating layer by using the plurality of first recesses of the hard mask in the cell area and forming a second opening in the interlayer insulating layer by using the second recess of the hard mask in the peripheral area, a seventh operation S170 of completely removing the hard mask in the cell area and the peripheral area, an eighth operation S180 of forming a contact forming layer that fills the plurality of first openings of the interlayer insulating layer in the cell area and the second opening of the interlayer insulating layer in the peripheral area, and a ninth operation S190 of polishing the contact forming layer to form a plurality of first contact structures in the cell area and a second contact structure in the peripheral area.

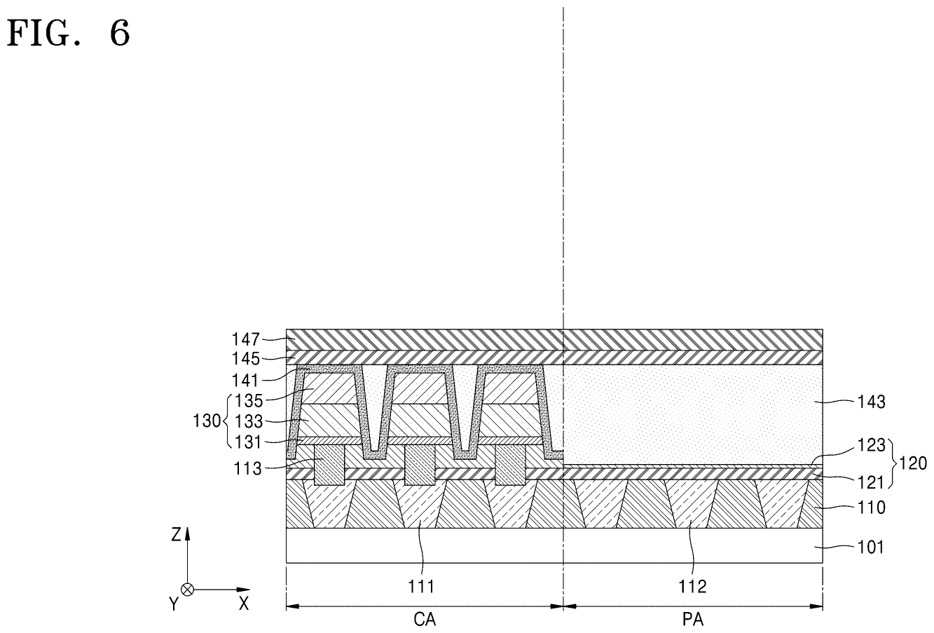

Technical characteristics of each of the first to ninth operations S110 to S190 will be described in detail with reference to FIGS. 6 to 23 described below.

FIGS. 6 to 23 are cross-sectional views showing a method of fabricating a variable resistance memory device in process order, according to embodiments of the present inventive concept.

Referring to FIG. 6, in an embodiment a substrate 101 having the cell area CA and the peripheral area PA surrounding the cell area CA (e.g., in a plan view) may be prepared.

In an embodiment, the substrate 101 may include a semiconductor wafer containing silicon (Si), germanium (Ge), silicon carbide (SiC), gallium arsenide (GaAs), indium arsenide (InAs), or indium phosphide (InP). In some embodiments, the substrate 101 may include an impurity-doped well or an impurity-doped structure that is a conductive area.

In some embodiments, a cell transistor may be formed on the substrate 101 in the cell area CA. In an embodiment, the cell transistor may be provided as a buried gate-type transistor. A peripheral circuit transistor may be formed on the substrate 101 in the peripheral area PA. The peripheral circuit transistor may be provided as a planar-type transistor.

A base insulating layer 110 may be formed on the substrate 101 (e.g., formed directly thereon in the Z direction), and a plurality of first plugs 111 and a plurality of second plugs 112 that are formed to pass through the base insulating layer 110 and contact the substrate 101 may be formed. For example, in an embodiment the plurality of first plugs 111 connected to the cell transistor or to a lower metal line may be formed in the cell area CA. Simultaneously, the plurality of second plugs 112 connected to the peripheral circuit transistor may be formed in the peripheral area PA.

In an embodiment, a lower insulating layer 120 may then be formed to cover the plurality of first plugs 111 and the plurality of second plugs 112 over the cell area CA and the peripheral area PA. In an embodiment, the lower insulating layer 120 may include a first lower insulating layer 121 and a second lower insulating layer 123 formed on (e.g., formed directly thereon in the Z direction) the first lower insulating layer 121.

In an embodiment, the first lower insulating layer 121 and the second lower insulating layer 123 may include different materials from each other. In some embodiments, the first lower insulating layer 121 may include a SiCN film, a SiOC film, a SiOF film, a SiCH film, a SiOCH film, or a combination thereof. In some embodiments, the second lower insulating layer 123 may be formed as a tetraethyl orthosilicate (TEOS) film. However, embodiments of the present inventive concept are not necessarily limited thereto.

In an embodiment, in the cell area CA, a plurality of pad electrodes 113 that are formed to pass through the lower insulating layer 120 and are in direct contact with and electrically connected to the plurality of first plugs 111 may be formed. For example, in an embodiment, a lower surface of each of the plurality of pad electrodes 113 may extend to a lower level (e.g., in the Z direction) than an upper surface of each of the plurality of first plugs 111. However, embodiments of the present inventive concept are not necessarily limited thereto.

In an embodiment, in the cell area CA, a plurality of MTJ structures 130 may then be formed in direct contact with and electrically connected to the plurality of pad electrodes 113. In an embodiment, a plurality of MTJ structures 130 may be arranged on cross points in a mesh structure in a first direction X (e.g., the X direction) and a second direction Y (e.g., the Y direction). The plurality of MTJ structures 130 may form memory cells. The plurality of MTJ structures 130 may be formed on the plurality of first plugs 111 in the cell area CA (e.g., in the Z direction). For example, the plurality of MTJ structures 130 may be electrically connected to the plurality of first plugs 111 through the plurality of pad electrodes 113. In an embodiment, the plurality of pad electrodes 113 may be directly connected to the plurality of first plugs 111 and the plurality of MTJ structures 130.

In some embodiments, each of the plurality of MTJ structures 130 may have a structure in which a lower electrode 131, an MTJ pattern 133, and an upper electrode 135 are stacked (e.g., consecutively stacked in the Z direction). The MTJ pattern 133 may constitute a variable resistance layer and, as described above with reference to FIGS. 2 and 3, may include the pinned layer PL, the tunnel barrier layer TBL, and the free layer FL. In an embodiment, the lower electrode 131 and the upper electrode 135 may include metal or metal nitride.

In an embodiment, in the cell area CA, a capping layer 141 may then be formed to conformally cover the entire plurality of MTJ structures 130 and an upper surface of the lower insulating layer 120. The capping layer 141 may be formed to protect the MTJ structures 130. In an embodiment, the capping layer 141 may cover both upper surfaces and lateral surfaces of the MTJ structures 130 and may extend between adjacent MTJ structures 130. In the present specification, the capping layer 141 may be referred to as an encapsulation layer. The capping layer 141 may include an insulating material. For example, in an embodiment the capping layer 141 may include silicon nitride (SiN).

In an embodiment, a buried insulating layer 143 may then be formed over the cell area CA and the peripheral area PA. In an embodiment, the cell area CA, the buried insulating layer 143 may fill a space between the MTJ structures 130 so that the space may not include any voids. In some embodiments, the buried insulating layer 143 may include silicon oxide (SiO) formed through a high density plasma (HDP) chemical vapor deposition process. However, embodiments of the present inventive concept are not necessarily limited thereto.

In an embodiment, stacked insulating stopper layers 145 and 147 may then be formed to cover the buried insulating layer 143 over the cell area CA and the peripheral area PA. In an embodiment, the stacked insulating stopper layers 145 and 147 may have a stack structure (e.g., consecutively stacked in the Z direction) of a lower insulating stopper layer 145 and an upper insulating stopper layer 147. In the present specification, the stacked insulating stopper layers 145 and 147 may be referred to as a first insulating stopper layer.

In some embodiments, the lower insulating stopper layer 145 and the upper insulating stopper layer 147 may include different materials from each other. For example, in an embodiment the lower insulating stopper layer 145 may include a SiCN film, and the upper insulating stopper layer 147 may include a TEOS film.

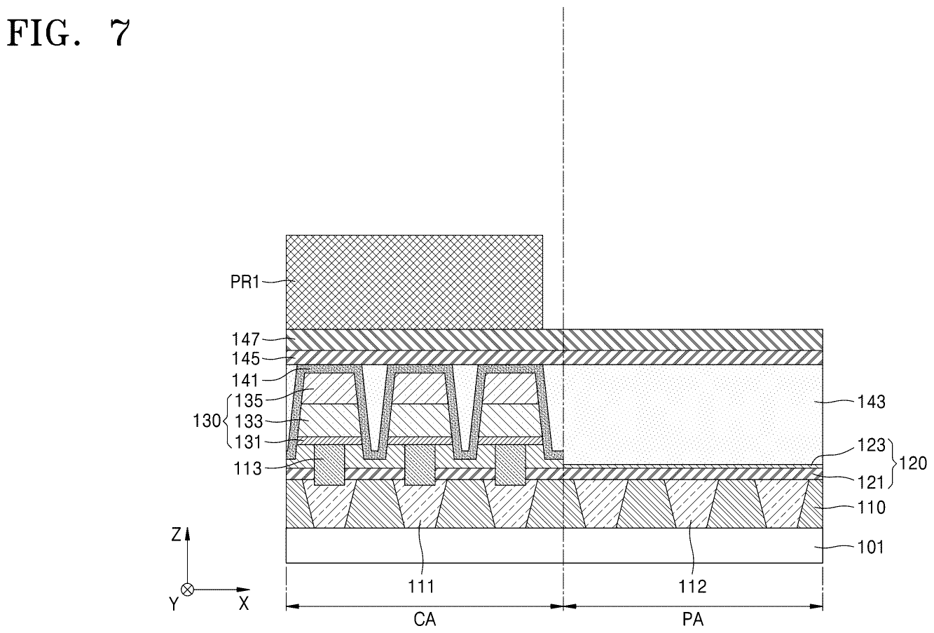

Referring to FIG. 7, a first photoresist pattern PR1 may be formed on the stacked insulating stopper layers 145 and 147 in the cell area CA. For example, in an embodiment the first photoresist pattern PR1 may be disposed directly thereon the upper insulating stopper layer 147 (e.g., in the Z direction).

The first photoresist pattern PR1 may be formed on the stacked insulating stopper layers 145 and 147 in the cell area CA and may be formed to cover all of the plurality of MTJ structures 130. In an embodiment, the first photoresist pattern PR1 may not be formed in the peripheral area PA.

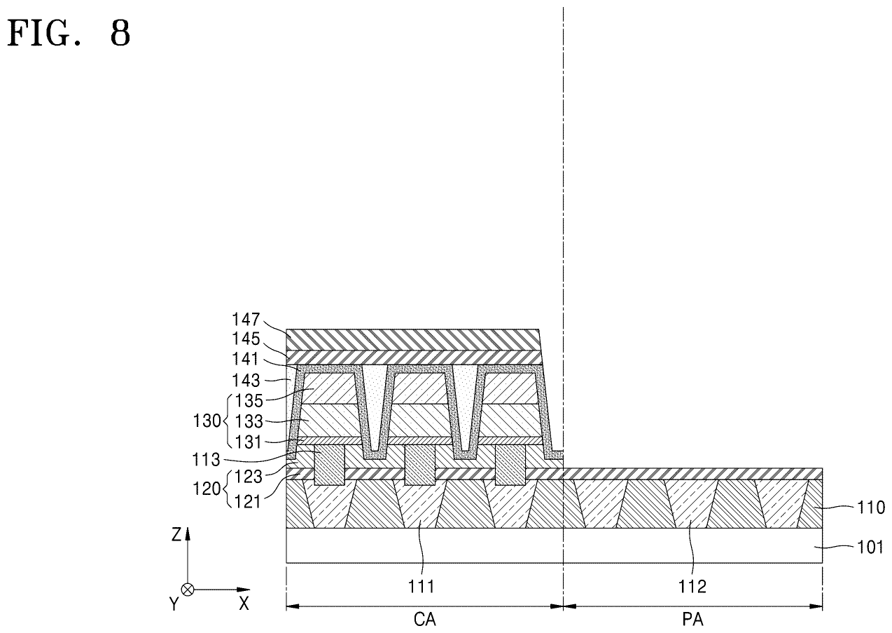

Referring to FIG. 8, in an embodiment a full etch process may be performed using the first photoresist pattern PR1 (refer to FIG. 7) as an etch mask and the first photoresist pattern PR1 may then be removed.

Due to the first photoresist pattern PR1 (refer to FIG. 7), the cell area CA may not be etched by the full etch process and only the peripheral area PA may be etched by the etch process. However, a portion of the capping layer 141 may be exposed at an edge of the cell area CA.

In contrast, all portions of the stacked insulating stopper layers 145 and 147, the capping layer 141, and the second lower insulating layer 123 in the peripheral area PA may be etched by the full etch process and the first lower insulating layer 121 may be exposed in the peripheral area PA.

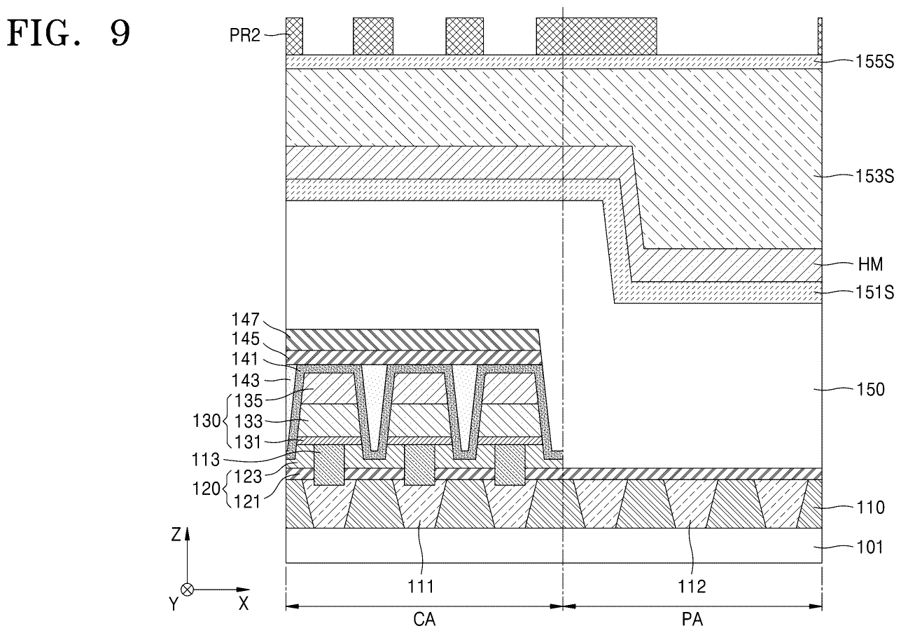

Referring to FIG. 9, over the cell area CA and the peripheral area PA, an interlayer insulating layer 150, a second insulating stopper layer 151S, a hard mask HM, a first upper sacrificial layer 153S, and a first anti-reflection film 155S may be formed sequentially (e.g., in the Z direction).

In some embodiments, the interlayer insulating layer 150 may include a different material from the buried insulating layer 143. In an embodiment, the interlayer insulating layer 150 may include a material with a low dielectric constant that is lower than that of silicon oxide. For example, in an embodiment the interlayer insulating layer 150 may include a material having a low dielectric constant less than 3.9, a low-k (LK) dielectric, an ultra low-k (ULK) dielectric, and/or an extreme low-k (ELK) dielectric. The interlayer insulating layer 150 may have a large step difference between the cell area CA and the peripheral area PA. For example, a vertical step may be formed in the interlayer insulating layer 150 between the cell area CA and the peripheral area PA. The large step difference may be due to the plurality of MTJ structures 130 formed in the cell area CA.

In an embodiment, the second insulating stopper layer 151S may then be formed to conformally cover the interlayer insulating layer 150, such as an upper surface of the interlayer insulating layer 150. In some embodiments, the second insulating stopper layer 151S may include a different material from the stacked insulating stopper layers 145 and 147. For example, in an embodiment the second insulating stopper layer 151S may include a SiON film.

In an embodiment, the hard mask HM may then be formed to conformally cover the second insulating stopper layer 151S. For example, in an embodiment the hard mask HM may be formed directly on an upper surface of the second insulating stopper layer 151S. In some embodiments, the hard mask HM may include a metal-containing material that has a high etch selectivity with respect to insulating materials, such as a conductive material. For example, in an embodiment the hard mask HM may include titanium nitride (TiN). In an embodiment, the material constituting the hard mask HM may be substantially the same as a material constituting the upper electrode 135 of the MTJ structure 130.

In an embodiment, the first upper sacrificial layer 153S may then be formed to cover the hard mask HM and have a flat upper surface. For example, in an embodiment the first upper sacrificial layer 153S may be formed directly on an upper surface of the hard mask HM. In some embodiments, the first upper sacrificial layer 153S may include a material that may form a flat upper surface by reducing the large step difference. For example, in an embodiment the first upper sacrificial layer 153S may include a spin-on hardmask (SOH) film including an organic compound.

In an embodiment, the first anti-reflection film 155S that covers the first upper sacrificial layer 153S and on which a second photoresist pattern PR2 is formed may then be formed. For example, in an embodiment the first anti-reflection film 155S may be formed directly on an upper surface of the first upper sacrificial layer 153S. For example, in an embodiment the first anti-reflection film 155S may include a SiON film.

In an embodiment, the second photoresist pattern PR2 may then be formed on the first anti-reflection film 155S (e.g., formed directly thereon in the Z direction). In an embodiment, a portion of the second photoresist pattern PR2, corresponding to the plurality of MTJ structures 130, may be formed to be opened in the cell area CA and a portion of the second photoresist pattern PR2, corresponding to the plurality of second plugs 112, may be formed to be opened in the peripheral area PA.

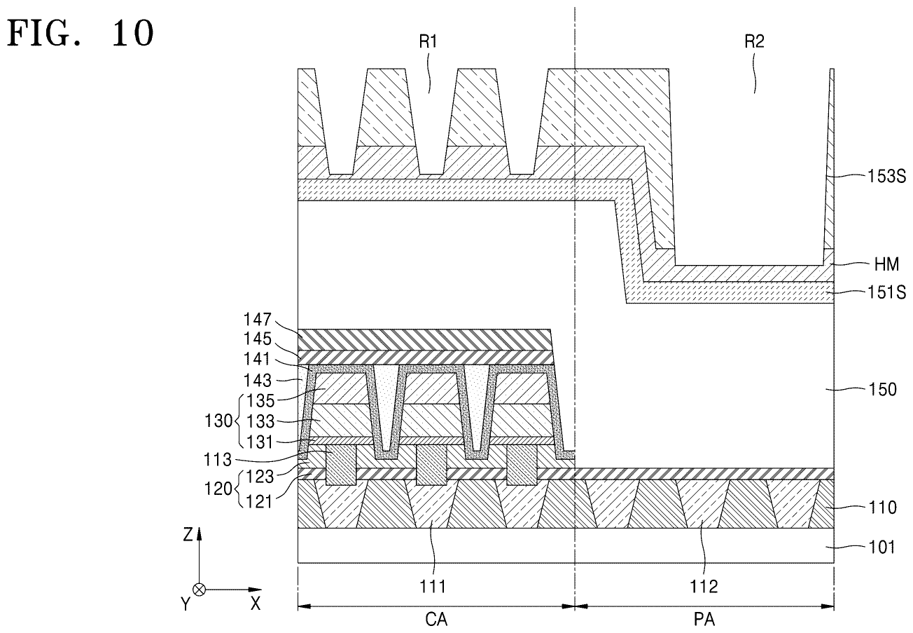

Referring to FIG. 10, an etch process may then be performed using the second photoresist pattern PR2 (refer to FIG. 9) as an etch mask.

In an embodiment, the etch process may be a dry etch process, and thus a plurality of first preliminary recesses R1 may be formed in the cell area CA and a second preliminary recess R2 may be formed in the peripheral area PA. Here, each of the plurality of first preliminary recesses R1 and the second preliminary recess R2 may be formed over the first upper sacrificial layer 153S and the hard mask HM.

In an embodiment, the second photoresist pattern PR2 (refer to FIG. 9) and the first anti-reflection film 155S (refer to FIG. 9) may then be removed.

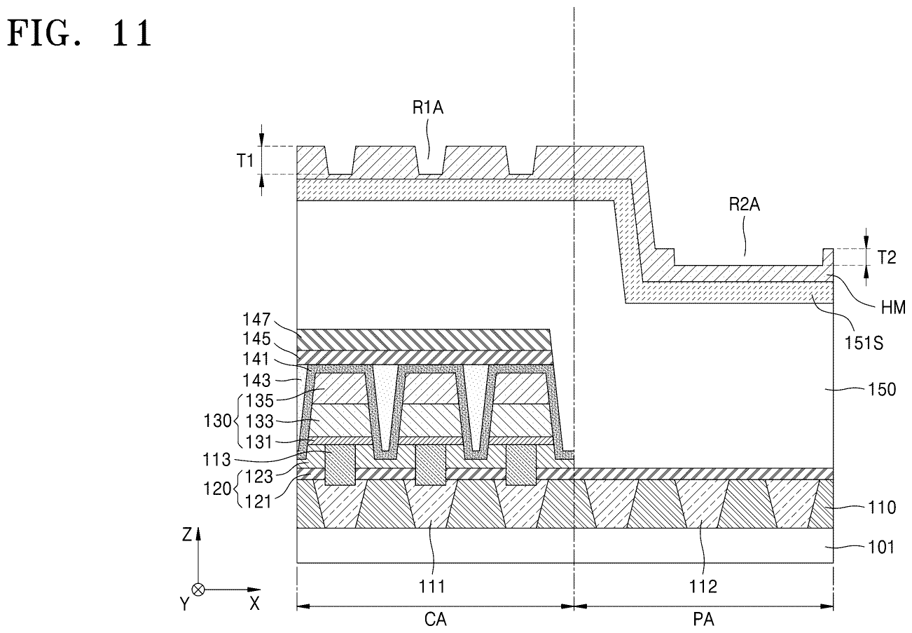

Referring to FIG. 11, in an embodiment the first upper sacrificial layer 153S (refer to FIG. 10) may be removed to completely expose the hard mask HM.

In the cell area CA, the hard mask HM may include a plurality of first recesses R1A corresponding to the plurality of first preliminary recesses R1 (refer to FIG. 10), and in the peripheral area PA, the hard mask HM may include a second recess R2A corresponding to the second preliminary recess R2 (refer to FIG. 10). In an embodiment, due to a difference in etching amount depending on an etching width, a depth T1 of the plurality of first recesses R1A may be greater than a depth T2 of the second recess R2A.

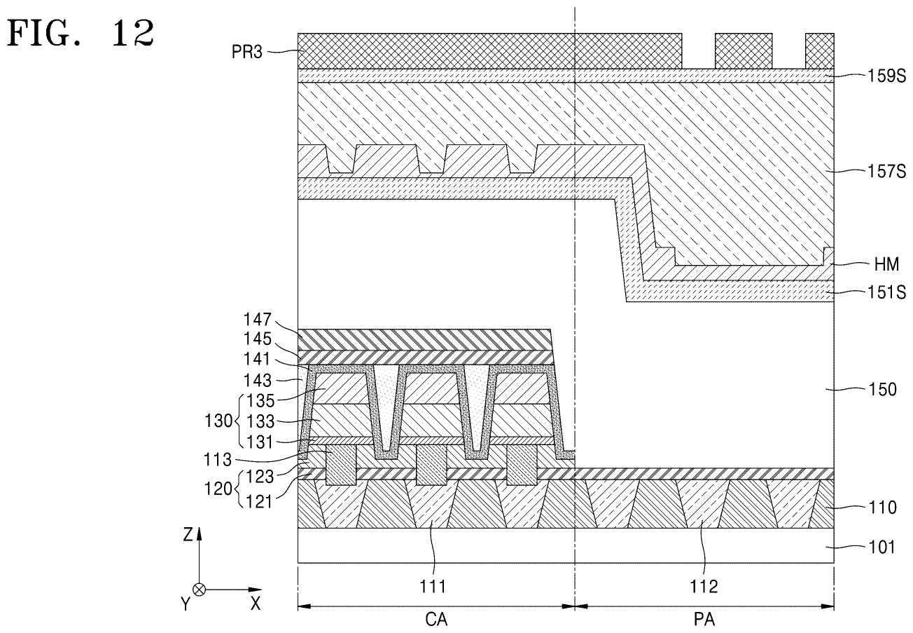

Referring to FIG. 12, a second upper sacrificial layer 157S and a second anti-reflection film 159S may be sequentially formed on the hard mask HM (e.g., in the Z direction) over the cell area CA and the peripheral area PA.

The second upper sacrificial layer 157S may be formed to cover the hard mask HM and have a flat upper surface. For example, in an embodiment the second upper sacrificial layer 157S may be formed directly on an upper surface of the hard mask HM (e.g., in the Z direction).

In some embodiments, the second upper sacrificial layer 157S may include a material that may form a flat upper surface by reducing the large step difference. For example, in an embodiment the second upper sacrificial layer 157S may include an SOH film including an organic compound.

In an embodiment, the second anti-reflection film 159S that covers the second upper sacrificial layer 157S and on which a third photoresist pattern PR3 is formed may then be formed. For example, in an embodiment the second anti-reflection film 159S may be formed directly on the second upper sacrificial layer 157S (e.g., in the Z direction). For example, in an embodiment the second anti-reflection film 159S may include a SiON film.

In an embodiment, the third photoresist pattern PR3 may then be formed on the second anti-reflection film 159S (e.g., formed directly thereon in the Z direction). In an embodiment, the third photoresist pattern PR3 may be formed to cover the entire cell area CA and a portion of the third photoresist pattern PR3, corresponding to the plurality of second plugs 112, may be formed to be opened solely in the peripheral area PA.

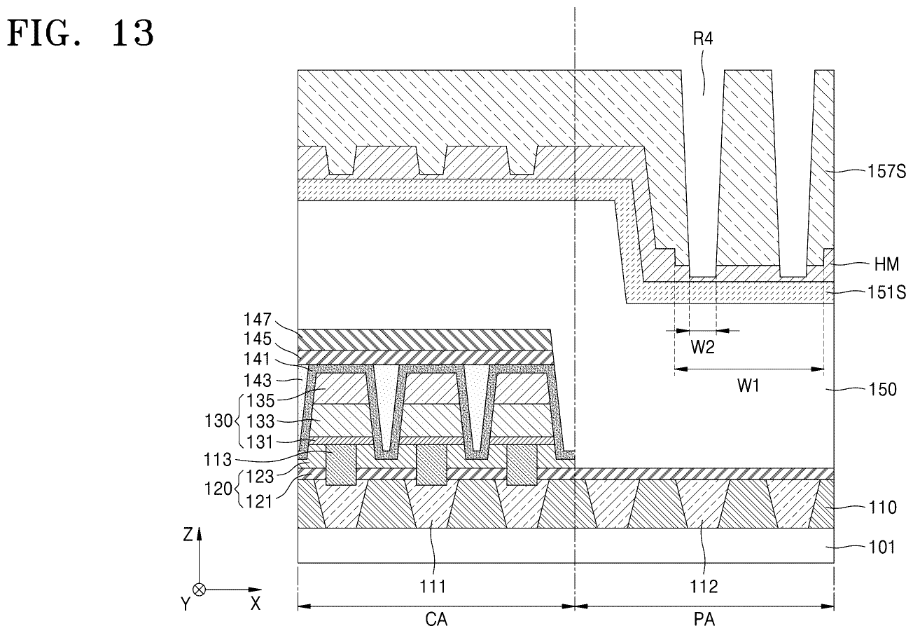

Referring to FIG. 13, an etch process may then be performed using the third photoresist pattern PR3 (refer to FIG. 12) as an etch mask.

In an embodiment, the etch process may be a dry etch process, and accordingly, a plurality of fourth preliminary recesses R4 may be formed in the peripheral area PA. The plurality of fourth preliminary recesses R4 may be formed over the second upper sacrificial layer 157S and the hard mask HM.

Accordingly, in the peripheral area PA, a relatively wide recess and a plurality of relatively narrow recesses in the wide recess may be formed in the hard mask HM. The wide recess may have a first horizontal width W1, and each of the plurality of narrow recesses may have a second horizontal width W2 that is less than the first horizontal width W1.

In an embodiment, the third photoresist pattern PR3 (refer to FIG. 12) and the second anti-reflection film 159S (refer to FIG. 12) may then be removed.

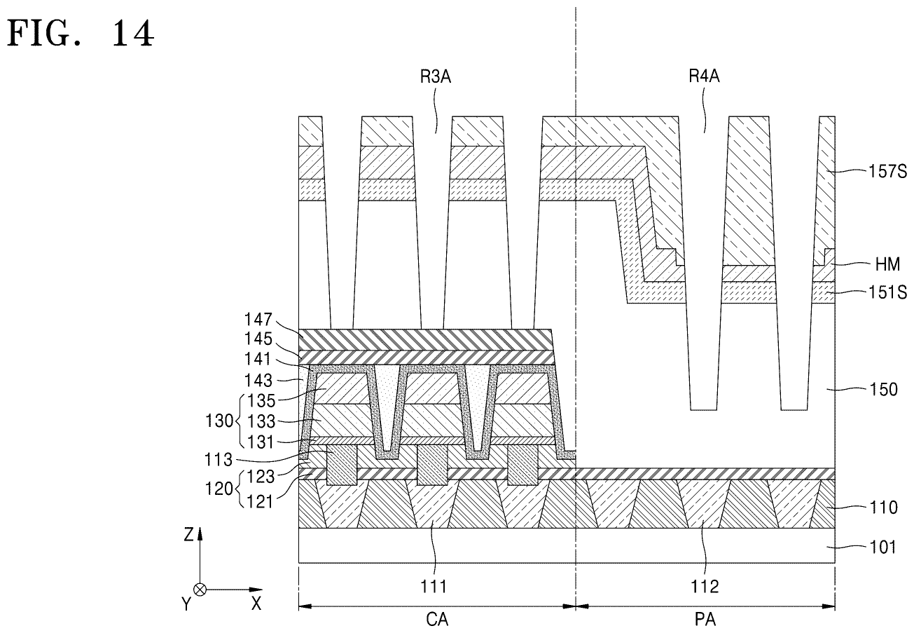

Referring to FIG. 14, in an embodiment an etching based on a pattern shape of the hard mask HM may be performed using a selective etch process.

In an embodiment, through the selective etch process, a plurality of third recesses R3A corresponding to the plurality of first recesses R1A (refer to FIG. 11) of the hard mask HM may be formed in the cell area CA. At the same time, a plurality of fourth recesses R4A corresponding to the plurality of fourth preliminary recesses R4 (refer to FIG. 13) may be formed in the peripheral area PA.

In some embodiments, the plurality of third recesses R3A may be formed to pass through the interlayer insulating layer 150 and upper surfaces of the corresponding stacked insulating stopper layers 145 and 147 may be exposed. For example, in an embodiment shown in FIG. 14 an upper surface of the upper insulating stopper layer 147 may be exposed. However, embodiments of the present inventive concept are not necessarily limited thereto. At the same time, the plurality of fourth recesses R4A may be formed to penetrate only a portion of the interlayer insulating layer 150.

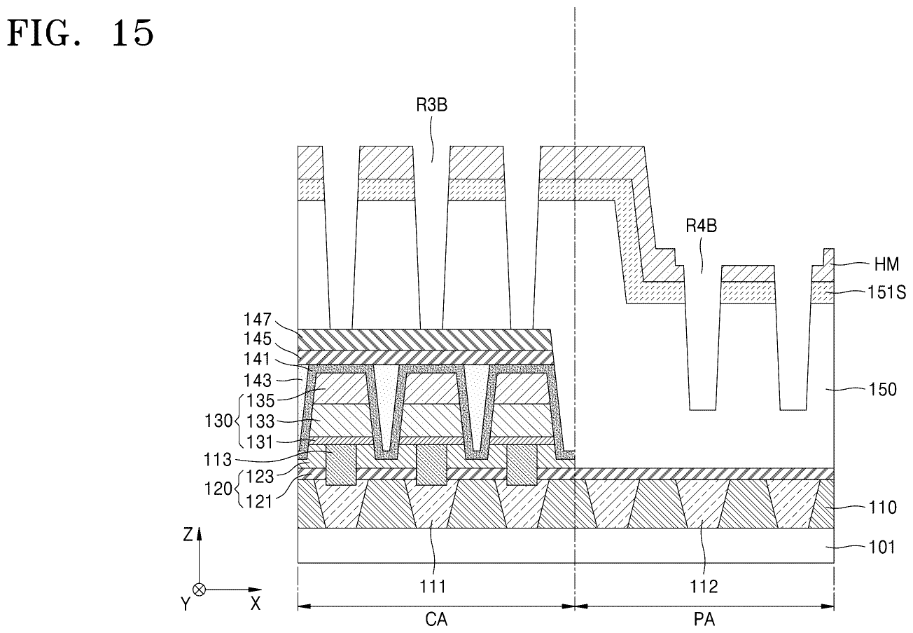

Referring to FIG. 15 the second upper sacrificial layer 157S (refer to FIG. 14) may be removed to completely expose the hard mask HM.

As the hard mask HM is completely exposed, a plurality of third subsequent recesses R3B may be formed in the cell area CA, and a plurality of fourth subsequent recesses R4B may be formed in the peripheral area PA.

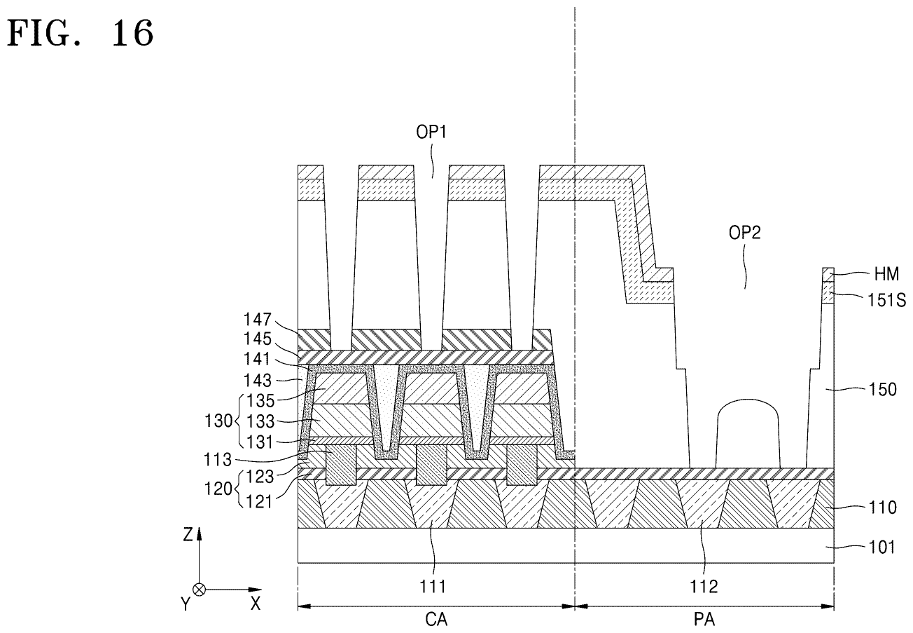

Referring to FIG. 16, in an embodiment an etching may be performed based on shapes of a plurality of third subsequent recesses R3B (refer to FIG. 15) and a plurality of fourth subsequent recesses R4B (refer to FIG. 15) by using a selective etch process.

In an embodiment, through the selective etch process, a plurality of first preliminary openings OP1 corresponding to the plurality of third subsequent recesses R3B (refer to FIG. 15) may be formed in the cell area CA. At the same time, a second preliminary opening OP2 corresponding to the plurality of fourth subsequent recesses R4B (refer to FIG. 15) may be formed in the peripheral area PA.

In some embodiments, the plurality of first preliminary openings OP1 may be formed to pass through the upper insulating stopper layer 147 and upper surfaces of the corresponding lower insulating stopper layer 145 may be exposed. At the same time, the second preliminary opening OP2 may be formed to pass through the interlayer insulating layer 150 and an upper surface of the corresponding first lower insulating layer 121 may be exposed. In an embodiment, the second preliminary opening OP2 may have an arch shape.

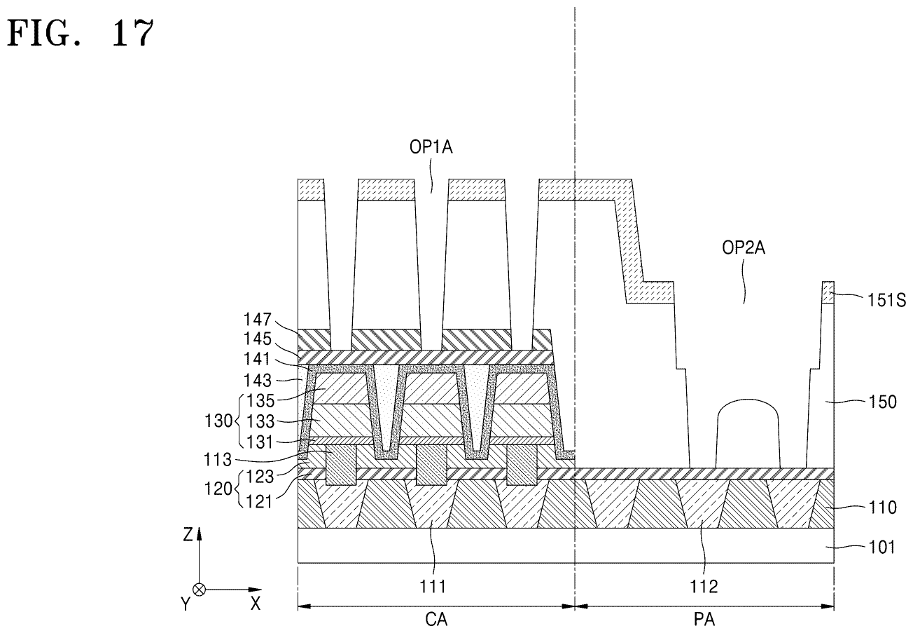

Referring to FIG. 17, the hard mask HM (refer to FIG. 16) may be completely removed to expose the second insulating stopper layer 151S.

As such, the hard mask HM (refer to FIG. 16) may be completely removed prior to a subsequent polishing process, thereby eliminating short circuit defects due to residues of a metal material contained in the hard mask HM (refer to FIG. 16) in subsequent fabricating processes.

In an embodiment, a plurality of first openings OP1A corresponding to the plurality of first preliminary openings OP1 (refer to FIG. 16) may be formed in the cell area CA. At the same time, a second opening OP2A corresponding to the second preliminary opening OP2 (refer to FIG. 16) may be formed in the peripheral area PA.

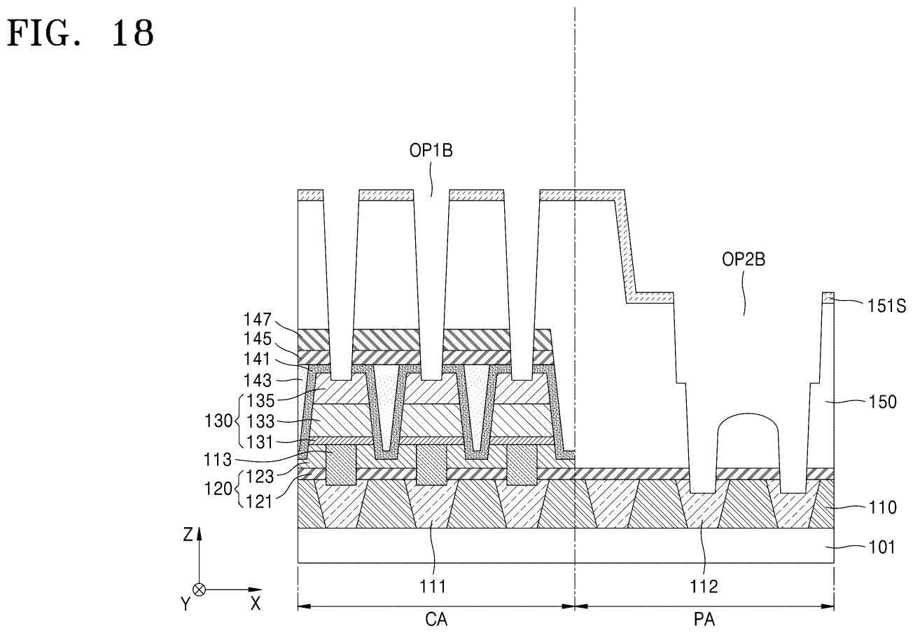

Referring to FIG. 18, in an embodiment an etching may be performed based on shapes of the plurality of first openings OP1A (refer to FIG. 17) and the second opening OP2A (refer to FIG. 17) by using a selective etch process.

In an embodiment, through the selective etch process, a plurality of first subsequent openings OP1B corresponding to the plurality of first openings OP1A (refer to FIG. 17) may be formed in the cell area CA. At the same time, a second subsequent opening OP2B corresponding to the second opening OP2A (refer to FIG. 17) may be formed in the peripheral area PA.

In some embodiments, the plurality of first subsequent openings OP1B may be formed to pass through the stacked insulating stopper layers 145 and 147 and the capping layer 141, and the upper electrode 135 of the corresponding one of the plurality of MTJ structures 130 may be exposed. At the same time, the second subsequent opening OP2B may be formed to pass through the first lower insulating layer 121 and the corresponding one of the plurality of second plugs 112 may be exposed.

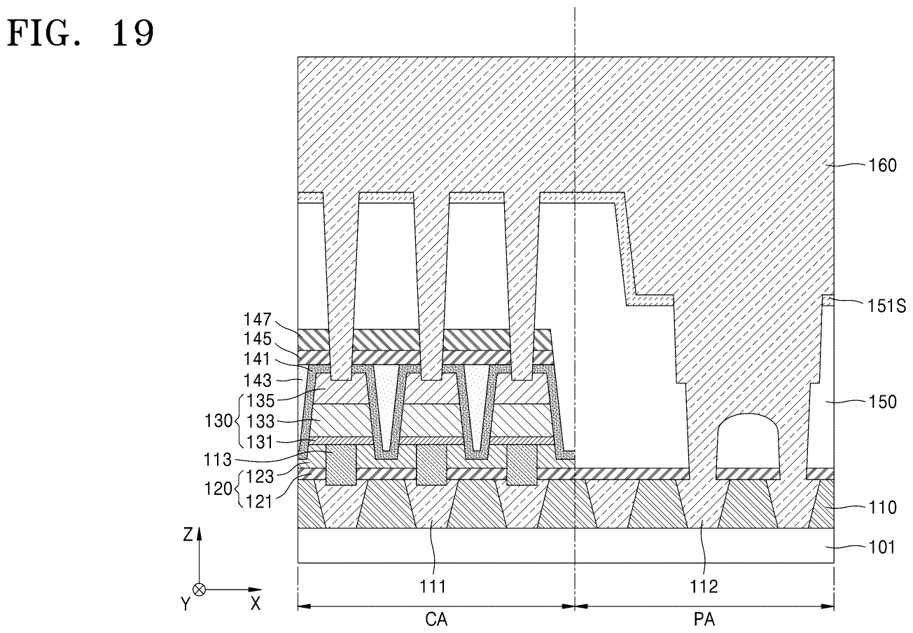

Referring to FIG. 19, in an embodiment a contact forming layer 160 may be formed to fill the plurality of first subsequent openings OP1B in the cell area CA and the second subsequent opening OP2B in the peripheral area PA.

In an embodiment, the contact forming layer 160 may be formed through an electroplating process. In some embodiments, the contact forming layer 160 satisfying a desired shape may be formed using a single plating process. For example, a conductive material constituting the contact forming layer 160 may include copper (Cu) or a copper (Cu) alloy. However, embodiments of the present inventive concept are not necessarily limited thereto.

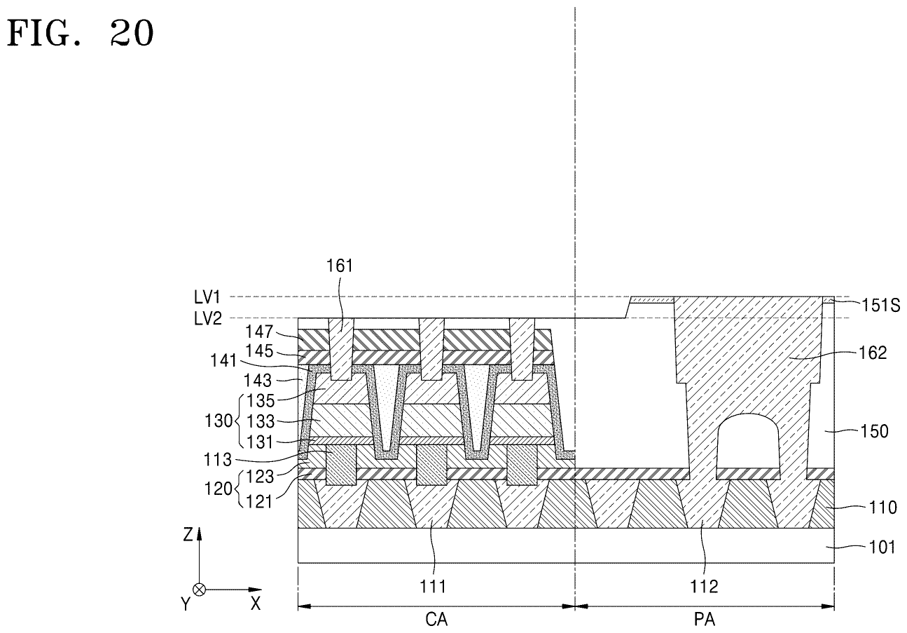

Referring to FIG. 20, in an embodiment a first polishing process that removes the second insulating stopper layer 151S from the cell area CA and uses the second insulating stopper layer 151S as an etch stop film in the peripheral area PA may be performed.

In an embodiment, the second insulating stopper layer 151S may be removed from the cell area CA by using a vertical level difference in the second insulating stopper layer 151S due to the large step difference between the cell area CA and the peripheral area PA. However, the second insulating stopper layer 151S in the peripheral area PA may function as an etch stop film. For example, in an embodiment the first polishing process may include a chemical mechanical polishing (CMP) process.

In an embodiment, by the first polishing process, a first level LV1 (e.g., a vertical level in the Z direction) of the uppermost surface of the second insulating stopper layer 151S exposed in the peripheral area PA may be higher than a second level LV2 (e.g., a vertical level in the Z direction) of the uppermost surface of the interlayer insulating layer 150 exposed in the cell area CA.

In an embodiment, by the first polishing process, the contact forming layer 160 (refer to FIG. 19) may be node-separated to define a plurality of first contact structures 161 in the cell area CA and define a second contact structure 162 in the peripheral area PA.

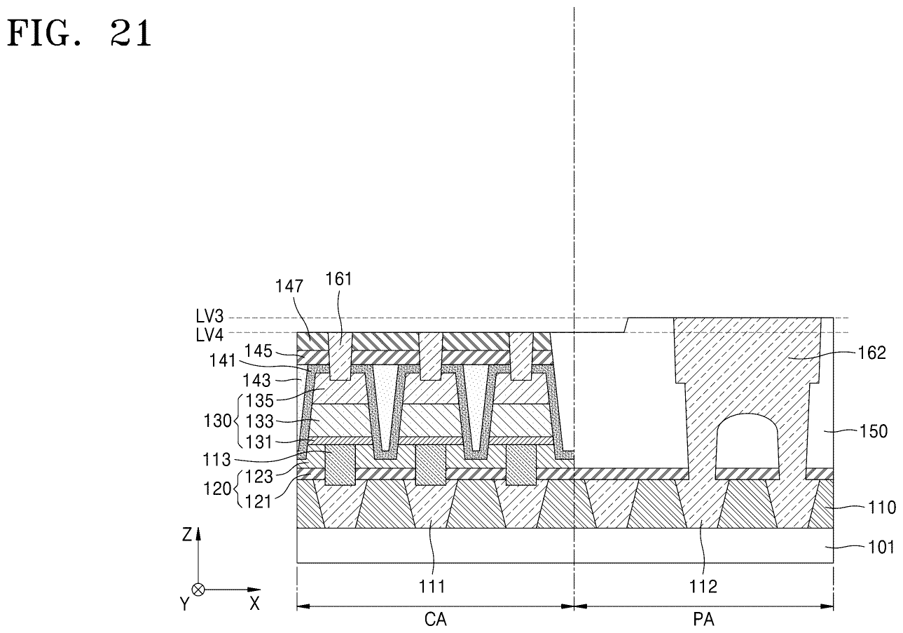

Referring to FIG. 21, in an embodiment a second polishing process that completely removes the second insulating stopper layer 151S (refer to FIG. 20) in the peripheral area PA and uses the stacked insulating stopper layers 145 and 147 as an etch stop film in the cell area CA may be performed.

In an embodiment, the interlayer insulating layer 150 may be removed from the cell area CA, and the second insulating stopper layer 151S (refer to FIG. 20) may be completely removed from the peripheral area PA. For example, in an embodiment the second polishing process may include a chemical mechanical polishing process. However, embodiments of the present inventive concept are not necessarily limited thereto.

In an embodiment, by the second polishing process, a third level LV3 (e.g., a vertical level in the Z direction) of the uppermost surface of the second contact structure 162 exposed in the peripheral area PA may be higher than a fourth level LV4 (e.g., a vertical level in the Z direction) of the uppermost surface of the stacked insulating stopper layers 145 and 147 exposed in the cell area CA.

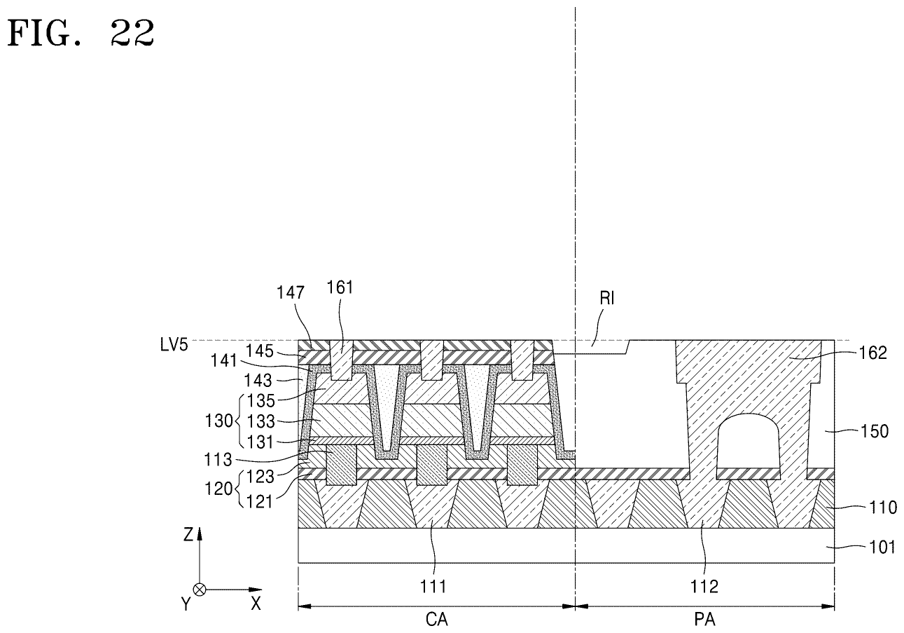

Referring to FIG. 22, in an embodiment a third polishing process that removes a portion of the upper insulating stopper layer 147 from the cell area CA and removes a portion of the second contact structure 162 from the peripheral area PA may be performed.

In an embodiment, the portion of the upper insulating stopper layer 147 may be removed from the cell area CA and the portion of the second contact structure 162 may be removed from the peripheral area PA. At the same time, the interlayer insulating layer 150 may be partially removed between the cell area CA and the peripheral area PA to form a boundary recess RI. For example, the boundary recess RI may be a recessed portion of the interlayer insulating layer 150 between the cell area CA and the peripheral area PA. In an embodiment, the third polishing process may include a chemical mechanical polishing process. However, embodiments of the present inventive concept are not necessarily limited thereto.

In an embodiment, through the third polishing process, a fifth level LV5 (e.g., a vertical level in the Z direction) of the uppermost surface of the plurality of first contact structures 161 exposed in the cell area CA and the fifth level LV5 (e.g., a vertical level in the Z direction) of the uppermost surface of the second contact structure 162 exposed in the peripheral area PA may be substantially the same as each other.

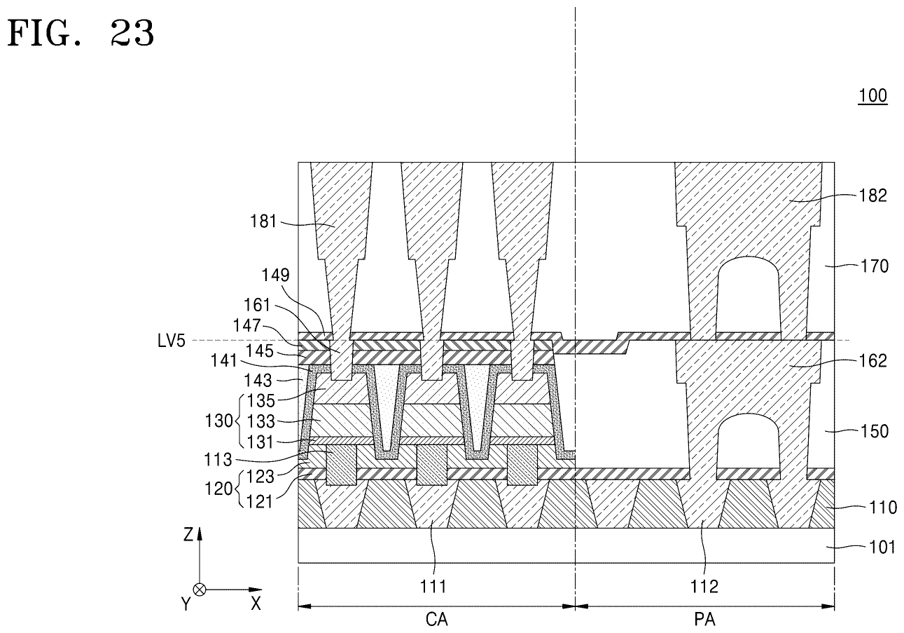

Referring to FIG. 23, in an embodiment a third insulating stopper layer 149 may be formed to conformally cover the upper insulating stopper layer 147 in the cell area CA, the interlayer insulating layer 150 in the peripheral area PA, and a boundary recess RI (refer to FIG. 22) of the interlayer insulating layer 150 between the cell area CA and the peripheral area PA.

Accordingly, in the cell area CA, the lower insulating stopper layer 145, the upper insulating stopper layer 147, and the third insulating stopper layer 149 may form a stopper layer stack structure. In some embodiments, the lower insulating stopper layer 145 and the third insulating stopper layer 149 may include the same material as each other, and the upper insulating stopper layer 147 and the third insulating stopper layer 149 may include different materials from each other.

In an embodiment, the fifth level LV5 (e.g., in the Z direction) of the uppermost surface of the upper insulating stopper layer 147 in the cell area CA may be substantially the same as the fifth level LV5 (e.g., in the Z direction) of the uppermost surface of the interlayer insulating layer 150 in the peripheral area PA.

In an embodiment, an upper interlayer insulating layer 170 may then be formed over the cell area CA and the peripheral area PA. In some embodiments, the upper interlayer insulating layer 170 may include substantially the same material as the interlayer insulating layer 150.

In an embodiment, a plurality of first upper contact structures 181 that are formed to pass through the third insulating stopper layer 149 and the upper interlayer insulating layer 170 and connected to (e.g., directly connected thereto) the plurality of first contact structures 161 may then be formed in the cell area CA. At the same time, a second upper contact structure 182 that are formed to pass through the third insulating stopper layer 149 and the upper interlayer insulating layer 170 and connected to (e.g., directly connected thereto) the second contact structure 162 may be formed in the peripheral area PA.

Through this fabricating process, a variable resistance memory device 100 according to an embodiment of the present inventive concept may be fabricated.

The method of fabricating the variable resistance memory device 100 according to an embodiment of the present inventive concept may completely remove the hard mask HM (refer to FIG. 16) containing a conductive material prior to a subsequent polishing process, and thus short-circuit defects due to residues of metal materials provided in the hard mask HM (refer to FIG. 16) may be completely blocked, thereby providing the variable resistance memory device 100 with high reliability.

The completed variable resistance memory device 100 according to an embodiment of the present inventive concept will be described as follows. The variable resistance memory device 100 may include the substrate 101 having the cell area CA and the peripheral area PA surrounding the cell area CA.

In an embodiment, in the cell area CA, the plurality of MTJ structures 130 constituting a plurality of memory cells may be disposed, the capping layer 141 covering the plurality of MTJ structures 130 may be disposed, and cell insulating stopper layers 145, 147, and 149 disposed on the capping layer 141 and having a multi-layer structure may be disposed.

In an embodiment, in the peripheral area PA, the interlayer insulating layer 150, at least a portion of which is disposed at the same vertical level (e.g., in the Z direction) as some of layers constituting the cell insulating stopper layers 145, 147, and 149 and which has a step difference, may be disposed, and the third insulating stopper layer 149 having a single-layer structure may be disposed on the interlayer insulating layer 150. In the present specification, the third insulating stopper layer 149 may be referred to as a peripheral insulating stopper layer.

In the cell area CA, the plurality of first contact structures 161 formed to pass through the cell insulating stopper layers 145, 147, and 149 and the capping layer 141 and connected to the plurality of MTJ structures 130 and the plurality of first upper contact structures 181 formed on (e.g. formed directly thereon in the Z direction) the plurality of first contact structures 161 may be disposed.

In the peripheral area PA, the second contact structure 162 formed to pass through the third insulating stopper layer 149 and the interlayer insulating layer 150 and connected to the plurality of second plugs 112 and the second upper contact structure 182 formed on the second contact structure 162 (e.g., formed directly thereon in the Z direction) may be disposed.

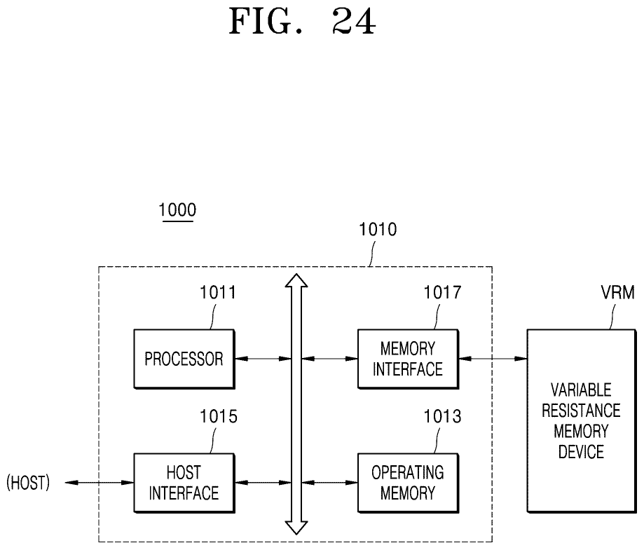

FIG. 24 is a configuration diagram of a data processing system including a variable resistance memory device according to an embodiment.

Referring to FIG. 24, a data processing system 1000 may include a memory controller 1010 connected between (e.g., electrically connected therebetween) a host and the variable resistance memory device VRM.

The memory controller 1010 may be configured to access the variable resistance memory device VRM in response to a request of the host.

The variable resistance memory device VRM may include the variable resistance memory device 100 fabricated using the method of fabricating a variable resistance memory device S100 described above. In an embodiment, the memory controller 1010 may include a processor 1011, an operating memory 1013, a host interface 1015, and a memory interface 1017.

The processor 1011 may control the overall operation of the memory controller 1010, and the operating memory 1013 may store applications, data, and control signals necessary for the memory controller 1010 to operate. In an embodiment, the host interface 1015 may perform protocol conversion for data/control signal exchange between the host and the memory controller 1010.

In an embodiment, the memory interface 1017 may perform protocol conversion for data/control signal exchange between the memory controller 1010 and the variable resistance memory device VRM. The configuration and operating characteristics of the variable resistance memory device VRM are the same as described above, and thus a detailed description thereof is omitted for economy of description.

The data processing system 1000 according to an embodiment of the present inventive concept may include a memory card. However, embodiments of the present inventive concept are not necessarily limited thereto.

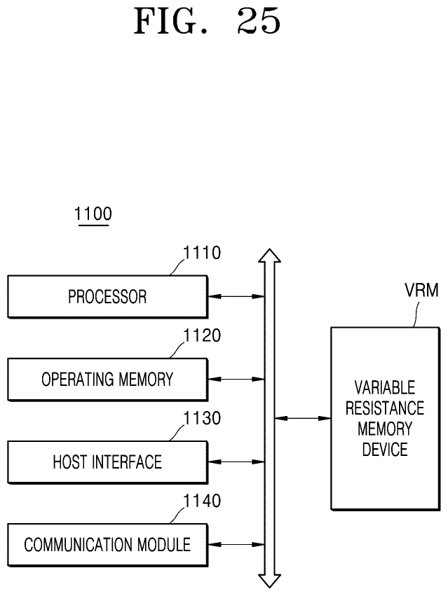

FIG. 25 is a configuration diagram of a data processing system including a variable resistance memory device according to an embodiment.

Referring to FIG. 25, in an embodiment a data processing system 1100 may include the variable resistance memory device VRM, a processor 1110, an operating memory 1120, and a user interface 1130, and, if necessary, may further include a communication module 1140.

In an embodiment, the variable resistance memory device VRM may include the variable resistance memory device 100 fabricated using the method of fabricating a variable resistance memory device S100 described above.

In an embodiment, the processor 1110 may be a central processing device. The operating memory 1120 stores application programs, data, control signals, and the like necessary for the data processing system 1100 to operate. The user interface 1130 provides an environment in which a user is capable of accessing the data processing system 1100 and provides the user with the data processing process and processing results of the data processing system 1100. The configuration and operating characteristics of the variable resistance memory device VRM are the same as described above, and thus a detailed description thereof is omitted for economy of description.

In an embodiment, the data processing system 1100 may be used as a disk device, as an internal/external memory card of a portable electronic device, as an image processor, or as an application chipset.

Although non-limiting embodiments have been described with reference to the attached drawings, those skilled in the art will understand that embodiments of the present inventive concept may be modified into other detailed forms without changing the technical idea or necessary aspects. Therefore, the described embodiments may be modified and should not be understood as limiting.

While the present inventive concept has been particularly shown and described with reference to non-limiting embodiments thereof, it will be understood that various changes in form and details may be made therein without departing from the spirit and scope of the present inventive concept.

What is claimed is:

1. A method of fabricating a variable resistance memory device, the method comprising:
preparing a substrate having a cell area and a peripheral area surrounding the cell area;
forming a plurality of magnetic tunnel junction (MTJ) structures in the cell area;
forming an interlayer insulating layer covering the cell area and the peripheral area, the interlayer insulating layer having a step difference between the cell area and the peripheral area;
forming a hard mask that conformally covers the interlayer insulating layer in the cell area and the peripheral area;
etching a portion of the hard mask to form a plurality of first recesses in the cell area and a second recess in the peripheral area;
forming a plurality of first openings in the interlayer insulating layer by using the plurality of first recesses of the hard mask in the cell area in a selective etch process and forming a second opening in the interlayer insulating layer by using the second recess of the hard mask in the peripheral area in the selective etch process;
completely removing the hard mask in the cell area and the peripheral area; and
forming a contact forming layer that fills the plurality of first openings of the interlayer insulating layer in the cell area and the second opening of the interlayer insulating layer in the peripheral area.

2. The method of claim 1, wherein:
each of the plurality of MTJ structures includes a lower electrode, an MTJ pattern, and an upper electrode that are stacked; and
a material of the upper electrode is substantially same as a material of the hard mask.

3. The method of claim 1, further comprising:
prior to the forming of the interlayer insulating layer, forming a first insulating stopper layer on the plurality of MTJ structures; and
prior to the forming of the hard mask, forming a second insulating stopper layer on the interlayer insulating layer.

4. The method of claim 3, further comprising,
after the forming of the contact forming layer, performing a first polishing of the contact forming layer to expose the interlayer insulating layer in the cell area and the second insulating stopper layer in the peripheral area by using the second insulating stopper layer as an etch stop layer.

5. The method of claim 4, wherein a vertical level of an uppermost surface of the interlayer insulating layer exposed in the cell area is less than a vertical level of an uppermost surface of the second insulating stopper layer exposed in the peripheral area.

6. The method of claim 5, further comprising, after performing the first polishing of the contact forming layer, performing a second polishing of the contact forming layer to expose the first insulating stopper layer in the cell area and the interlayer insulating layer in the peripheral area by using the first insulating stopper layer as an etch stop layer.

7. The method of claim 6, wherein a vertical level of an uppermost surface of the first insulating stopper layer exposed in the cell area is substantially a same as a vertical level of an uppermost surface of the interlayer insulating layer exposed in the peripheral area.

8. The method of claim 7, wherein a portion of the interlayer insulating layer positioned between the cell area and the peripheral area is recessed.

9. The method of claim 8, further comprising forming a third insulating stopper layer that conformally covers the first insulating stopper layer exposed in the cell area, the interlayer insulating layer exposed in the peripheral area, and the recess of the interlayer insulating layer between the cell area and the peripheral area.

10. The method of claim 9, further comprising forming a plurality of first contact structures passing through the third insulating stopper layer in the cell area and a second contact structure passing through the third insulating stopper layer in the peripheral area.

11. A method of fabricating a variable resistance memory device, the method comprising:
preparing a substrate having a cell area and a peripheral area surrounding the cell area;
forming a plurality of magnetic tunnel junction (MTJ) structures in the cell area;
forming a capping layer covering the plurality of MTJ structures in the cell area;
forming a first insulating stopper layer on the capping layer in the cell area;
forming an interlayer insulating layer covering the cell area and the peripheral area, the interlayer insulating layer having a step difference between the cell area and the peripheral area;
forming a second insulating stopper layer that conformally covers the interlayer insulating layer in the cell area and the peripheral area;
forming a hard mask that conformally covers the second insulating stopper layer in the cell area and the peripheral area;
etching a portion of the hard mask to form a plurality of first recesses in the cell area and a second recess in the peripheral area;
forming a plurality of first openings passing through the second insulating stopper layer and the interlayer insulating layer by using the plurality of first recesses of the hard mask in the cell area in a selective etch process and forming a second opening passing through the second insulating stopper layer and the interlayer insulating layer by using the second recess of the hard mask in the peripheral area in the selective etch process;
completely removing the hard mask in the cell area and the peripheral area;
forming a contact forming layer that fills the plurality of first openings of the interlayer insulating layer in the cell area and the second opening of the interlayer insulating layer in the peripheral area;
performing a first polishing of the contact forming layer to expose the interlayer insulating layer in the cell area and the second insulating stopper layer in the peripheral area; and
performing a second polishing of the contact forming layer to expose the first insulating stopper layer in the cell area and the interlayer insulating layer in the peripheral area.

12. The method of claim 11, wherein:
the plurality of first recesses of the hard mask overlap the plurality of MTJ structures in a vertical direction; and
the second recess of the hard mask includes a wide recess having a first horizontal width and a plurality of narrow recesses within the wide recess, each of the plurality of narrow recesses having a second horizontal width less than the first horizontal width.

13. The method of claim 12, wherein the second opening of the interlayer insulating layer has an arch shape by a selective etching using the wide recess and the plurality of narrow recesses having different horizontal widths of the second recess of the hard mask.

14. The method of claim 11, wherein the first insulating stopper layer and the second insulating stopper layer include different materials from each other.

15. The method of claim 11, wherein a vertical level of an uppermost surface of the first insulating stopper layer is lower than a vertical level of a lowermost surface of the second insulating stopper layer.

16. A variable resistance memory device comprising:
a substrate having a cell area and a peripheral area surrounding the cell area;
a plurality of magnetic tunnel junction (MTJ) structures disposed in the cell area, the plurality of MTJ structures constituting a plurality of memory cells;
a capping layer covering the plurality of MTJ structures in the cell area;
a cell insulating stopper layer disposed on the capping layer, the cell insulating stopper layer having a multi-layer structure in the cell area;
an interlayer insulating layer, at least a portion of the interlayer insulating layer is disposed at a same vertical level as some layers of the multi-layer structure of the cell insulating stopper layer, the interlayer insulating layer having a step difference in the peripheral area;
a peripheral insulating stopper layer disposed on the interlayer insulating layer and having a single-layer structure in the peripheral area;
a plurality of first contact structures passing through the cell insulating stopper layer and the capping layer and connected to the plurality of MTJ structures in the cell area; and
a second contact structure passing through the peripheral insulating stopper layer and the interlayer insulating layer and connected to the substrate in the peripheral area,
wherein an uppermost layer of the multi-layer structure of the cell insulating stopper layer is connected to the peripheral insulating stopper layer.

17. The variable resistance memory device of claim 16, wherein:
the cell insulating stopper layer includes a stack structure of first to third stopper layers;
the first stopper layer and the third stopper layer include a same material as each other; and
the second stopper layer and the third stopper layer include different materials from each other.

18. The variable resistance memory device of claim 17, wherein a vertical level of an uppermost surface of the second stopper layer in the cell area is substantially same as a vertical level of an uppermost surface of the interlayer insulating layer in the peripheral area.

19. The variable resistance memory device of claim 17, wherein:
the third stopper layer and the peripheral insulating stopper layer include a same material as each other; and
the third stopper layer is directly connected to the peripheral insulating stopper layer to form an upper insulating stopper layer.

20. The variable resistance memory device of claim 19, wherein a portion of the upper insulating stopper layer between the cell area and the peripheral area is recessed.
